(19) United States
(12) Patent Application Publication
(10) Pub. No.: US 2026/0323979 A1
(43) Pub. Date: Oct. 15, 2026

(54) BURIED CHANNEL AIGaN BUFFER TRANSISTORS

(71) Applicant: Analog Devices, Inc., Wilmington, MA (US)

(72) Inventors: James G. Fiorenza, Carlisle, MA (US); Leonard Shtargot, Campbell, CA (US); Daniel Piedra, Somerville, MA (US); Xiaowei Cai, Belmont, MA (US); Guanghai Ding, Bedford, MA (US); Jung-Han Hsia, Wilmington, MA (US); Chandan Joishi, Wilmington, MA (US)

(21) Appl. No.: 19/398,982

(22) Filed: Nov. 24, 2025

Related U.S. Application Data
(60) Provisional application No. 63/725,354, filed on Nov. 26, 2024.
(60) Provisional application No. 63/737,577, filed on Dec. 20, 2024.

(51) Int. Cl. H10D 30/47; H10D 30/01; H10D 62/85; H10D 64/00

(52) U.S. Cl. CPC H10D 30/474; H10D 30/015; H10D 30/475; H10D 62/8503; H10D 64/112

(57) ABSTRACT

A GaN or AlGaN channel transistor device is described that uses a buried channel and improved field management to improve the Ron*Area and Ron*Qoss figures of merit. Various techniques for implementing buried channel AlGaN buffer field-effect transistors (FETs) that utilize high aluminum content buffers, differentiated top and buried channel compositions, advanced field management approaches, and alternative fabrication methods to push high voltage GaN devices closer to their theoretical performance limits are described. Techniques to manufacture AlGaN enhancement mode devices with high critical field capability and small Ron*Area characteristics that are difficult to achieve with conventional single-channel approaches, while maintaining compatibility with established manufacturing processes and gate structures are also described.

### CLAIM OF PRIORITY

This application claims priority to U.S. Provisional Application No. 63/737,577, titled “ALGAN COMPOUND SEMICONDUCTOR DEVICES” to James G. Fiorenza et al., filed Dec. 20, 2024, and U.S. Provisional Application No. 63/725,354, titled “BURIED CHANNEL AIGaN BUFFER TRANSISTORS” to James G. Fiorenza et al., filed Nov. 26, 2024, which are hereby incorporated by reference herein in their entireties.

### FIELD OF THE DISCLOSURE

This document pertains generally, but not by way of limitation, to semiconductor devices and processing, and more particularly but not by way of limitation to compound semiconductor devices.

### BACKGROUND

Gallium nitride (GaN) based semiconductors offer several advantages over other semiconductors as the material of choice for fabricating the next generation of transistors, or semiconductor devices, for use in both high voltage and high frequency applications. GaN based semiconductors, for example, have a wide bandgap that enable devices fabricated from these materials to have a high breakdown electric field and to be robust to a wide range of temperatures.

The two-dimensional electron gas (2DEG) channels formed by GaN based heterostructures generally have high electron mobility, making devices fabricated using these structures useful in power-switching and amplification systems. GaN based semiconductors, however, are typically used to fabricate depletion mode (or normally on) devices, which may have limited use in many of these systems, such as due to the added circuit complexity required to support such devices.

### SUMMARY OF THE DISCLOSURE

This disclosure describes a GaN or AlGaN channel transistor device that uses a buried channel and improved field management to improve the Ron*Area and Ron*Qoss figures of merit. This disclosure describes various techniques for implementing buried channel AlGaN buffer field-effect transistors (FETs) that utilize high aluminum content buffers, differentiated top and buried channel compositions, advanced field management approaches, and alternative fabrication methods to push high voltage GaN devices closer to their theoretical performance limits. This disclosure describes techniques to manufacture AlGaN enhancement mode devices with high critical field capability and small Ron*Area characteristics that are difficult to achieve with conventional single-channel approaches, while maintaining compatibility with established manufacturing processes and gate structures.

In some aspects, this disclosure is directed to a compound semiconductor heterostructure transistor device including multiple two-dimensional electron gas channels, the compound semiconductor heterostructure transistor device comprising: a substrate; a first semiconductor material layer formed over the substrate; a second semiconductor material layer formed over the first semiconductor material layer to form a first compound semiconductor heterostructure including a buried first two-dimensional electron gas (2DEG) channel, wherein the buried first 2DEG channel is more electrically conductive than either the first semiconductor material layer or the second semiconductor material layer; a third semiconductor material layer formed over a fourth semiconductor material layer, wherein the fourth semiconductor material layer is formed over the substrate, to form a second compound semiconductor heterostructure including a topside second 2DEG channel, wherein the topside second 2DEG channel is more electrically conductive than either the third semiconductor material layer or the fourth semiconductor material layer, and wherein the buried first 2DEG channel is different in composition from the topside second 2DEG channel; a drain electrode electrically coupled with the buried first 2DEG channel; a source electrode electrically coupled with the topside second 2DEG channel; and a gate electrode formed over the third semiconductor material layer.

In some aspects, this disclosure is directed to a method of forming a compound semiconductor heterostructure transistor device including multiple two-dimensional electron gas channels, the method comprising: forming a first semiconductor material layer over a substrate; forming a second semiconductor material layer over the first semiconductor material layer to form a first compound semiconductor heterostructure including a buried first two-dimensional electron gas (2DEG) channel, wherein the buried first 2DEG channel is more electrically conductive than either the first semiconductor material layer or the second semiconductor material layer; forming a third semiconductor material layer over a fourth semiconductor material layer, wherein the fourth semiconductor material layer is formed over the substrate, to form a second compound semiconductor heterostructure including a topside second 2DEG channel, wherein the topside second 2DEG channel is more electrically conductive than either the third semiconductor material layer or the fourth semiconductor material layer, and wherein the buried first 2DEG channel is different in composition from the topside second 2DEG channel; electrically coupling a drain electrode with the buried first 2DEG channel; electrically coupling a source electrode with the topside second 2DEG channel; and forming a gate electrode over the third semiconductor material layer.

In some aspects, this disclosure is directed to a compound semiconductor heterostructure transistor device including multiple two-dimensional electron gas channels in combination with an integrated circuit, the combination comprising: a substrate; a first semiconductor material layer formed over the substrate; a second semiconductor material layer formed over the first semiconductor material layer to form a first compound semiconductor heterostructure including a buried first two-dimensional electron gas (2DEG) channel, wherein the buried first 2DEG channel is more electrically conductive than either the first semiconductor material layer or the second semiconductor material layer; a third semiconductor material layer formed over a fourth semiconductor material layer, wherein the fourth semiconductor material layer is formed over the substrate, to form a second compound semiconductor heterostructure including a topside second 2DEG channel, wherein the topside second 2DEG channel is more electrically conductive than either the third semiconductor material layer or the fourth semiconductor material layer, and wherein the buried first 2DEG channel is different in composition from the topside second 2DEG channel; a first drain electrode electrically coupled with the buried first 2DEG channel; a first source electrode electrically coupled with the topside second 2DEG channel; and a first gate electrode formed over the third semiconductor material layer; and the integrated circuit including: a second gate electrode coupled with the fourth semiconductor material layer; a second drain electrode coupled with the fourth semiconductor material layer; and a second source electrode coupled with the fourth semiconductor material layer and the first source electrode, wherein the integrated circuit is positioned on a top surface of the compound semiconductor heterostructure transistor device.

### BRIEF DESCRIPTION OF THE DRAWINGS

In the drawings, which are not necessarily drawn to scale, like numerals may describe similar components in different views. The drawings illustrate generally, by way of example, but not by way of limitation, various embodiments discussed in the present document.

FIG. 1 depicts an example of a transistor device in accordance with this disclosure.

FIG. 2 depicts another example of a transistor device in accordance with this disclosure.

FIG. 3 depicts another example of a transistor device in accordance with this disclosure.

FIG. 4 depicts another example of a transistor device in accordance with this disclosure.

FIG. 5 depicts another example of a transistor device in accordance with this disclosure.

FIG. 6 depicts another example of a transistor device in accordance with this disclosure.

FIG. 7 depicts another example of a transistor device in accordance with this disclosure.

FIG. 8 depicts another example of a transistor device in accordance with this disclosure.

FIG. 9 depicts another example of a transistor device in accordance with this disclosure.

FIG. 10 is a flow diagram of an example of a method of forming a compound semiconductor heterostructure transistor device including multiple two-dimensional electron gas channels.

### DETAILED DESCRIPTION

The present inventors have recognized a fundamental problem with existing gallium nitride (GaN) power devices. Although GaN devices demonstrate better on-resistance (Ron) multiplied by Area (Ron*Area) and on-resistance multiplied by output charge (Ron*Qoss) figures of merit as compared to silicon devices, GaN devices remain far from their theoretical performance limits. The Ron*Area figure of merit represents the product of the on-resistance (Ron) of the device and the active area of the device, where a smaller Ron*Area value indicates better performance through either lower resistance for a given device size or the same resistance achieved with a smaller device area. The Ron*Qoss figure of merit represents the product of the on-resistance (Ron) and the output charge (Qoss) of the device, where Qoss is related to the output capacitance and represents the charge to be moved to switch the device between its on and off states. A lower Ron*Qoss value indicates better switching performance for high-frequency applications where both low resistance and fast switching are desirable.

The present inventors have further recognized that conventional GaN transistors face competing design requirements. For example, it may be desirable that a channel underneath the gate terminal be lightly doped for easy enhancement mode operation while simultaneously desirable that they have heavier doping or higher charge concentrations in the non-gated regions for adequate current carrying capacity and low on-resistance. Additionally, conventional approaches are limited by the use of GaN buffers or low aluminum percentage AlGaN materials, which restrict the achievable critical field strength and overall device performance.

This disclosure describes a GaN or AlGaN channel transistor device that uses a buried channel and improved field management to improve the Ron*Area and Ron*Qoss figures of merit. This disclosure describes various techniques for implementing buried channel AlGaN buffer field-effect transistors (FETs) that utilize high aluminum content buffers, differentiated top and buried channel compositions, advanced field management approaches, and alternative fabrication methods to push high voltage GaN devices closer to their theoretical performance limits. This disclosure describes techniques to manufacture AlGaN enhancement mode devices with high critical field capability and small Ron*Area characteristics that are difficult to achieve with conventional single-channel approaches, while maintaining compatibility with established manufacturing processes and gate structures.

As used in this disclosure, a GaN-based compound semiconductor material may include a chemical compound of elements including gallium (Ga), nitrogen (N), and one or more elements from different groups in the periodic table. Such chemical compounds may include a pairing of elements from group 13 (i.e., the group comprising boron (B), aluminum (Al), gallium (Ga), indium (In), and thallium (Tl)) with elements from group 15 (i.e., the group comprising nitrogen (N), phosphorus (P), arsenic (As), antimony (Sb), and bismuth (Bi)). Group 13 of the periodic table may also be referred to as Group III and group 15 as Group V. In an example, a semiconductor device may be fabricated from GaN and aluminum indium gallium nitride (AlInGaN).

Heterostructures described herein may be formed as AlN/GaN/AlN hetero-structures, InAlN/GaN heterostructures, AlGaN/GaN heterostructures, or heterostructures formed from other combinations of group 13 and group 15 elements. These heterostructures may form a two-dimensional electron gas (2DEG) at the interface of the compound semiconductors that form the heterostructure, such as the interface of GaN and AlGaN. The 2DEG may form a conductive channel of electrons that may be controllably depleted, such as by an electric field formed by a buried layer of p-type material disposed below the channel. The conductive channel of electrons may also be controllably enhanced, such as by an electric field formed by a gate terminal disposed above the channel to control a current through the semiconductor device. Semiconductor devices formed using such conductive channels may include high electron mobility transistors.

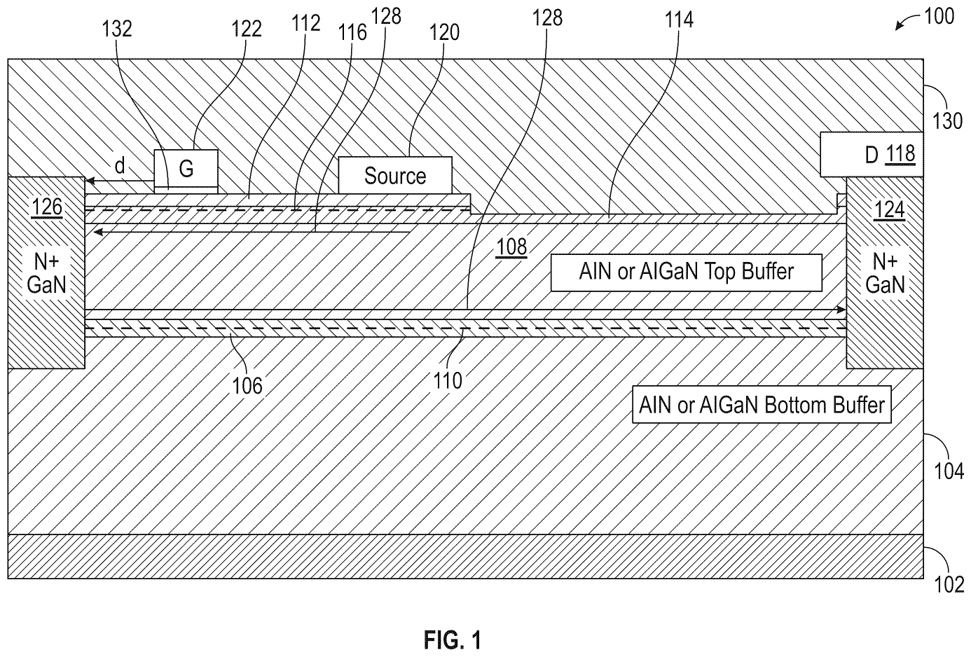

FIG. 1 depicts an example of a transistor device 100 in accordance with this disclosure. FIG. 1 is a cross-sectional view. The transistor device 100 is an example of a compound semiconductor heterostructure transistor device including multiple two-dimensional electron gas channels.

The transistor device 100 includes a substrate, such as silicon (Si), sapphire, silicon carbide (SiC), or an engineered substrate such as SiC-on-poly-AlN (aluminum nitride). A bottom buffer layer 104, such as aluminum nitride (AlN) or aluminum gallium nitride (AlGaN), is formed over the substrate 102.

A first semiconductor material layer 106, e.g., gallium nitride (GaN), is formed over the bottom buffer layer 104. A second semiconductor material layer 108, e.g., a top buffer layer, is formed over the first semiconductor material layer 106 to form a first compound semiconductor heterostructure. The second semiconductor material layer 108 may include AlN or AlGaN.

The first compound semiconductor heterostructure includes a buried first two-dimensional electron gas (2DEG) 110, where the buried first 2DEG channel 110 is more electrically conductive than either the first semiconductor material layer 106 or the second semiconductor material layer 108. The buried first 2DEG channel 110 is located at the interface of the first semiconductor material layer 106 and the second semiconductor material layer 108. In some examples, the transistor device 100 includes a single buried first 2DEG channel, as shown in FIG. 1. In other examples, the 100 includes two or more buried first 2DEG channels.

The transistor device 100 further includes a third semiconductor material layer 112 formed over a fourth semiconductor material layer 114 to form a first compound semiconductor heterostructure, which includes a topside second 2DEG channel 116, where the topside second 2DEG channel 116 is more electrically conductive than either the third semiconductor material layer 112 or the fourth semiconductor material layer 114. The topside second 2DEG channel 116 is located at the interface of the third semiconductor material layer 112 and the fourth semiconductor material layer 114. The fourth semiconductor material layer 114 may include GaN, and the third semiconductor material layer 112 may include AlN or AlGaN. The fourth semiconductor material layer 114 is formed over the second semiconductor material layer 108, e.g., the top buffer layer.

The transistor device 100 further includes a drain electrode 118 electrically coupled with the buried first 2DEG channel 110 through the first conductive material 124, a source electrode 120 electrically coupled with the topside second 2DEG channel 116, and a gate electrode 122 electrically coupled with the third semiconductor material layer 112. In some examples, a passivation layer is formed above the third semiconductor material layer 112.

The transistor device 100 further includes a first conductive material 124 that extends vertically from the drain electrode 118 to the bottom buffer layer 104 and electrically couples the buried first 2DEG channel 110 and the drain electrode 118. In the example shown, the first conductive material 124 is electrically coupled with and extends below the drain electrode 118. The transistor device 100 further includes a second conductive material 126 that extends vertically between and electrically couples the buried first 2DEG channel 110 and the topside second 2DEG channel 116. In some examples, the second conductive material 126 is laterally offset from the gate electrode in a plane parallel with the third semiconductor material layer 112 by at least a distance d along a plane parallel to the third semiconductor material layer 112 and on a side of the gate electrode 122 opposite the source electrode 120. In some examples, the first conductive material 124 and the second conductive material 126 include N+ GaN. A passivation layer 130 may be formed above the third semiconductor material layer 112.

A current path 128 is shown in FIG. 1. Current flows leftward in the topside second 2DEG channel 116 from the source electrode 120 to the second conductive material 126, downward through the second conductive material 126 to the buried first 2DEG channel 110, then rightward through the buried first 2DEG channel 110 to the first conductive material 124, and then upward through the first conductive material 124 to the drain electrode 118.

In accordance with this disclosure, the second semiconductor material layer 108 and the third semiconductor material layer 112 are different in composition and, as such, the buried first 2DEG channel 110 and the topside second 2DEG channel 116 are different in composition. For example, the topside second 2DEG channel 116 may be formed using an AlGaN/GaN combination (or an AlN/GaN combination) of the third semiconductor material layer 112 and the fourth semiconductor material layer 114, respectively. In this way, a standard p-GaN enhancement mode transistor device by inserting a p-GaN layer 132 in between the third semiconductor material layer 112 and the gate 122 may be made. In addition, the buried first 2DEG channel 110 may be formed using an GaN/AlN combination of the first semiconductor material layer 106 and the second semiconductor material layer 108, respectively.

In one example, the topside second 2DEG channel 116 is formed using an AlGaN/GaN combination and the buried first 2DEG channel 110 is formed using an AlN/GaN combination and, as such, their compositions and 2DEG channel conductivities are different. In another example, the topside second 2DEG channel 116 is formed using an AlGaN/GaN combination and the buried first 2DEG channel 110 is also formed using an AlGaN/GaN combination, but the content of aluminum in the topside second 2DEG channel 116 is different from the content of aluminum in the buried first 2DEG channel and, as such, their compositions are different. In both examples, the compositions of the two 2DEG channels are different. In this manner, the buried first 2DEG channel 110 has a different number of electrons, e.g., a different charge density, than that of the topside second 2DEG channel 116. This is desirable because the buried first 2DEG channel 110 and the topside second 2DEG channel 116 perform different functions in the transistor device 100. For example, the buried first 2DEG channel 110 is used to sustain a voltage with high critical field capability, thereby allowing very short source-drain distances with low resistance whereas the topside second 2DEG channel 116 is used to turn the transistor device 100 on and off.

In some examples, the first semiconductor material layer 106 includes GaN or a lower aluminum percentage AlGaN, while the second semiconductor material layer 108 includes AlN or high aluminum percentage AlGaN, such as above 50% aluminum content.

An advantage of this technique of using different compositions to form the buried first 2DEG channel 110 and the topside second 2DEG channel 116 is that an AlGaN channel device may be made with a high critical field and therefore a small Ron*Area, where Ron is the on-resistance of the transistor device, Area is the effective conduction area of the transistor device, and Ron*Area is the product of Ron and Area. In this case, the topside second 2DEG channel 116 may be made similar to the top channel in conventional GaN devices, and therefore a standard p-GaN enhancement mode structure may be used. In this way, an AlGaN enhancement mode device may be made.

In addition, in some examples, the threshold voltage (Vt) of the transistor device 100 may be increased by decreasing charge density of the topside second 2DEG channel 116 without hurting the Ron*Area. In some examples, the topside second 2DEG channel 116 is designed to have a very lightly concentrated 2DEG, such as around 5E12 electrons per centimeter squared, for easy enhancement mode operation, while the buried first 2DEG channel 110 may have a higher concentration, such as around 1E13 electrons per centimeter squared, to carry current and provide low on-resistance.

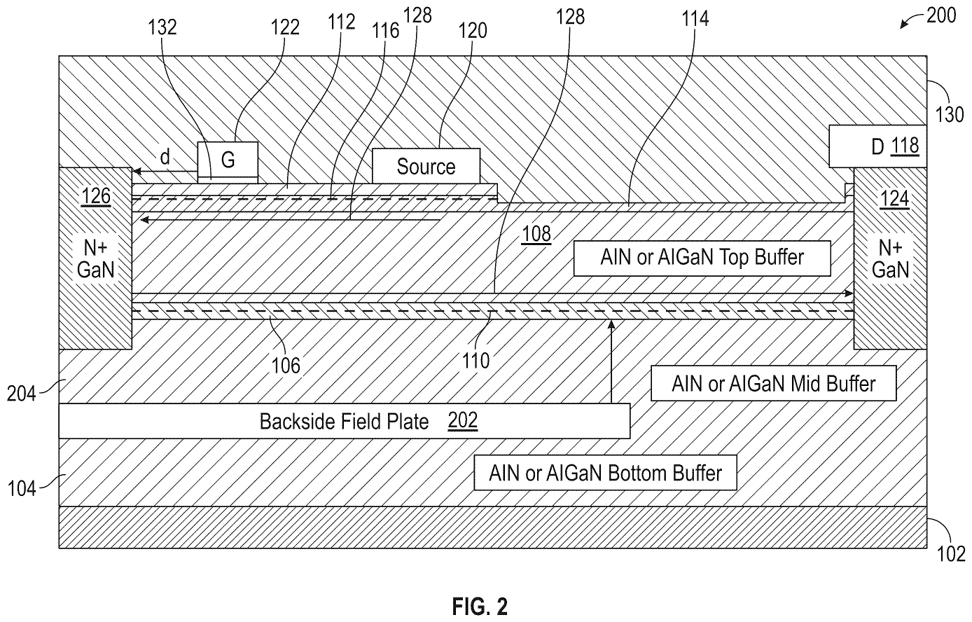

FIG. 2 depicts another example of a transistor device 200 in accordance with this disclosure. FIG. 2 is a cross-sectional view. The transistor device 200 is another example of a compound semiconductor heterostructure transistor device including multiple two-dimensional electron gas channels. Many of the components in FIG. 2 are similar to corresponding components shown in FIG. 1 and are identified by similar reference numbers. For brevity, these components are not described in detail again.

Like in FIG. 1, the transistor device 200 includes a buried first 2DEG channel 110 formed at the interface between the first semiconductor material layer 106 and the second semiconductor material layer 108 and a topside second 2DEG channel 116 formed at the interface between the third semiconductor material layer 112 and the fourth semiconductor material layer 114.

In some examples, the transistor device 200 further includes a backside field plate 202 formed between the substrate 102 and the buried first 2DEG channel 110.

The bottom buffer layer 104 is formed first, e.g., grown, and then the backside field plate 202 is formed over the bottom buffer layer 104. Then, the middle buffer layer 204 is formed, e.g., grown, between the backside field plate 202 and the buried first 2DEG channel 110. In some examples, the middle buffer layer 204 includes AlN or AlGaN. Eventually, the second semiconductor material layer 108, e.g., the top buffer layer, is formed, e.g., grown, between the buried first 2DEG channel 110 and the topside second 2DEG channel 116. In some examples, top buffer layer includes AlN or AlGaN. In some examples, a high temperature, such as greater than 1200 degrees Celsius, a Metal-Organic Chemical Vapor Deposition (MOCVD) reactor may be used to grow AlN and achieve high quality, smooth, and low dislocation films.

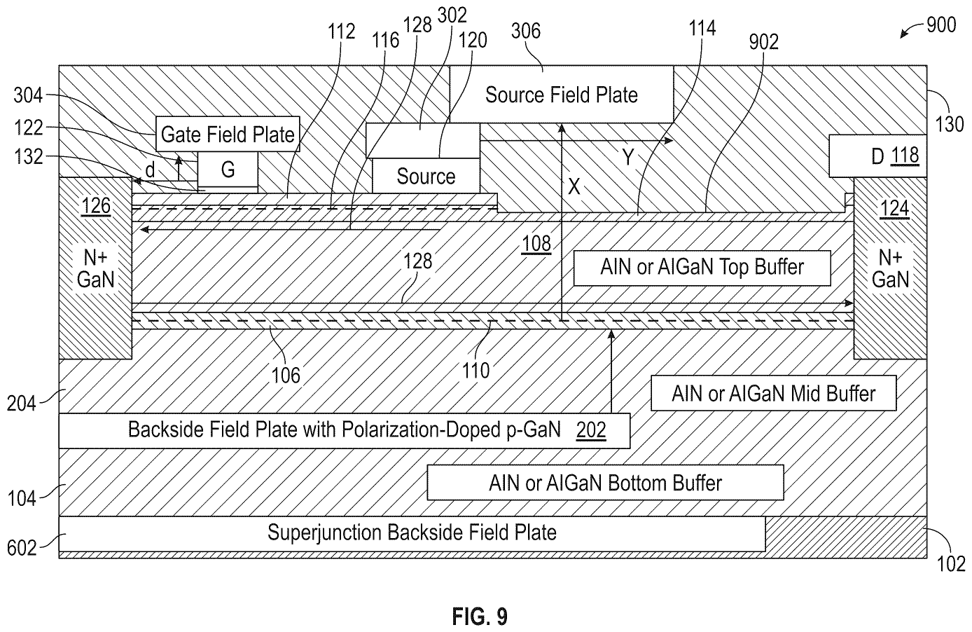

The techniques shown in FIG. 2 may be combined with the techniques in FIG. 1, or any of the other techniques of this disclosure, all of which being shown combined in FIG. 9.

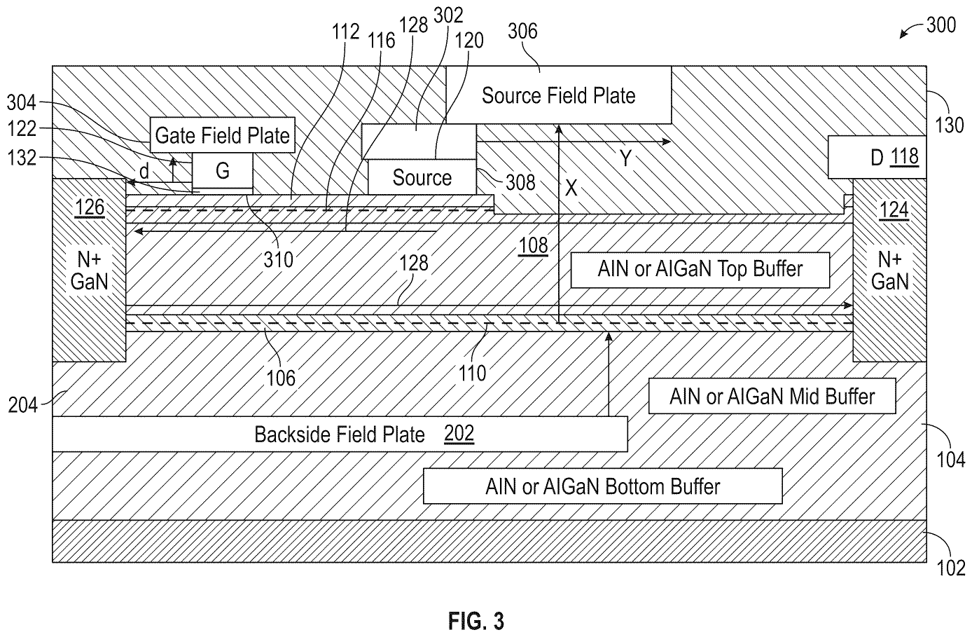

FIG. 3 depicts another example of a transistor device 300 in accordance with this disclosure. FIG. 3 is a cross-sectional view. The transistor device 300 is another example of a compound semiconductor heterostructure transistor device including multiple two-dimensional electron gas channels. Many of the components in FIG. 3 are similar to corresponding components shown in FIG. 1 and FIG. 2 and are identified by similar reference numbers. For brevity, these components are not described in detail again.

In accordance with this disclosure, the source electrode 120 is configured to operate as a first source field plate with respect to the buried first 2DEG channel 110. As seen in FIG. 3, the transistor device 300 includes a first source field plate 302 in electrical contact with and formed above the source electrode 120. The buried first 2DEG channel 110 may formed at a specific distance X beneath the source electrode 120 so that the buried first 2DEG channel 110 pinches off at the correct drain voltage for optimum field management.

In addition, the transistor device 300 may include a second source field plate 306 in electrical contact with and formed above the first source field plate 302. In some examples, the second source field plate 306 extends laterally in a plane parallel with the third semiconductor material layer 112 beyond an end 308 of the source electrode 120 by at least a distance Y along a plane parallel to the third semiconductor material layer 112 and on a side of the source electrode 120 opposite the gate electrode 122.

In addition, the transistor device 300 may include a gate field plate 304 in electrical contact with the gate electrode 122. The gate field plate 304 extends laterally beyond an end 310 of the gate electrode 122 by at least some distance along a plane parallel to the third semiconductor material layer 112 and on a side of the gate electrode 122 opposite the source electrode 120.

As a non-limiting example for purposes of explanation only, the gate field plate 304 has a pinch-off voltage of 20 volts (V), which limits the voltage seen by the gate electrode 122 to 20 V. Then the first source field plate 302 has a pinch-off voltage of 80 V, and the second source field plate 306 has a pinch off voltage of 320 V.

The transistor device 200 further includes a backside field plate 202 formed between the substrate 102 and the buried first 2DEG channel 110. In some examples, the backside field plate 202 is formed with polarization doped p-type GaN.

The bottom buffer layer 104 is formed first, e.g., grown, and then the backside field plate 202 is formed over the bottom buffer layer 104. Then, the middle buffer layer 204 is formed, e.g., grown, between the backside field plate 202 and the buried first 2DEG channel 110. In some examples, the middle buffer layer 314 includes AlN or AlGaN. Eventually, the second semiconductor material layer 108, e.g., the top buffer layer, is formed, e.g., grown, between the buried first 2DEG channel 110 and the topside second 2DEG channel 116. In some examples, the top buffer layer includes AlN or AlGaN. In some examples, a high temperature, such as greater than 1200 degrees Celsius, a Metal-Organic Chemical Vapor Deposition (MOCVD) reactor may be used to grow AlN and achieve high quality, smooth, and low dislocation films.

In some examples, the source electrode 120 length is designed to act well as a field plate. For example, the source electrode 120 length is five to ten times more than the distance between the source and the backside field plate 202.

The techniques shown in FIG. 3 may be combined with the techniques in either or both of FIGS. 1 and 2, or any of the other techniques of this disclosure, all of which being shown combined in FIG. 9.

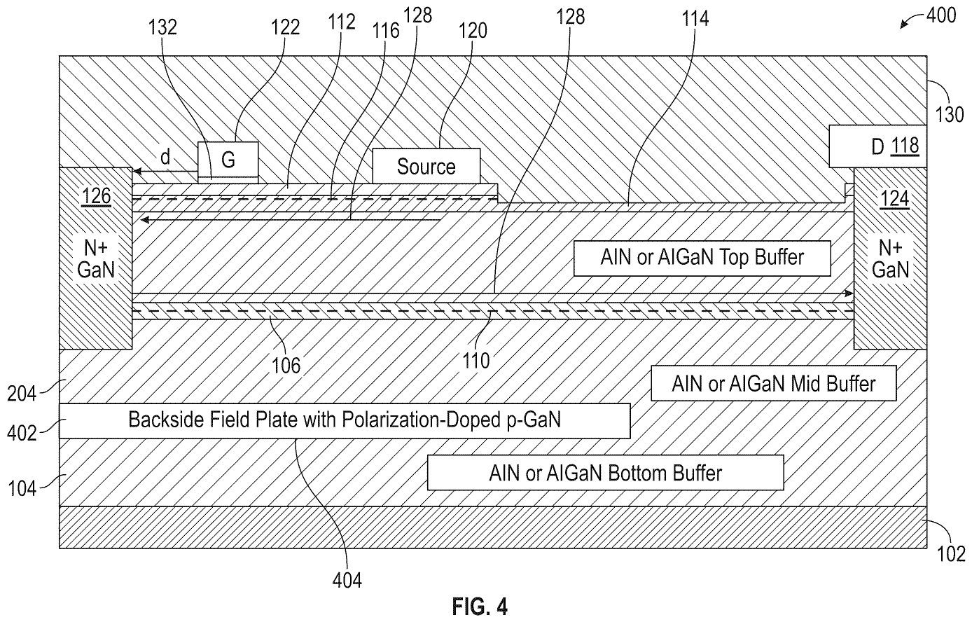

FIG. 4 depicts another example of a transistor device 400 in accordance with this disclosure. FIG. 4 is a cross-sectional view. The transistor device 400 is another example of a compound semiconductor heterostructure transistor device including multiple two-dimensional electron gas channels. Many of the components in FIG. 4 are similar to corresponding components shown in FIG. 1 through FIG. 3 and are identified by similar reference numbers. For brevity, these components are not described in detail again.

In accordance with this disclosure, piezoelectric doping is used to create p-type regions without relying on traditional magnesium doping methods. The technique involves grading an aluminum fraction in an AlGaN layer, specifically reducing the aluminum percentage spatially from a higher aluminum percentage to a lower aluminum percentage during the growth process. As seen in FIG. 4, the transistor device 400 includes a backside field plate 402, such as AlGaN, that includes a doped region 404, such as formed by piezoelectric doping. Piezoelectric doping is a method of inducing charge carriers in a semiconductor structure by utilizing strain-induced polarization at an interface between two materials to form a high concentration of electrons or holes without introducing intentional impurity dopants. The doped region 404 may be formed by grading an aluminum fraction in an AlGaN layer from a higher aluminum percentage to a lower aluminum percentage and even to GaN, where a doping concentration is proportional to a rate of change of the aluminum fraction.

The p-type doping concentration achieved through this method is proportional to the rate of change of the aluminum fraction. When the aluminum fraction is rapidly decreased over a short spatial distance, a higher concentration of p-type doping is generated, and when the aluminum fraction is gradually decreased over a longer spatial distance, a lower concentration of p-type doping results. This relationship exists because the p-type doping concentration is proportional to the spatial derivative or slope of the aluminum fraction profile.

In some examples, the fabrication process begins with growing a layer where the aluminum fraction is graded downward from high to low aluminum content. Following the growth of this graded layer, selective etching is performed to create openings or holes in the graded region at specific locations where electrical contact to the p-type region is desired. After the etching step, a regrowth process is carried out to complete the device structure, effectively creating a buried p-type layer that functions as a field plate when electrically connected to the source electrode 120.

Piezoelectric doping approach offers advantages over conventional magnesium-based p-type doping techniques. Traditional magnesium doping of buried p-type GaN is challenging to achieve because hydrogen present during MOCVD growth may deactivate the magnesium dopants. Additionally, magnesium doping typically exhibits low activation efficiency, with activated fractions often less than 10%, resulting in numerous trap states within the p-type doped material that may degrade device performance.

This approach provides a more reliable and controllable method for creating effective p-type regions for backside field plate applications while avoiding the activation and reliability challenges associated with conventional magnesium-doped GaN materials.

The techniques shown in FIG. 4 may be combined with the techniques in one or more of FIG. 1 through FIG. 3, or any of the other techniques of this disclosure, all of which being shown combined in FIG. 9.

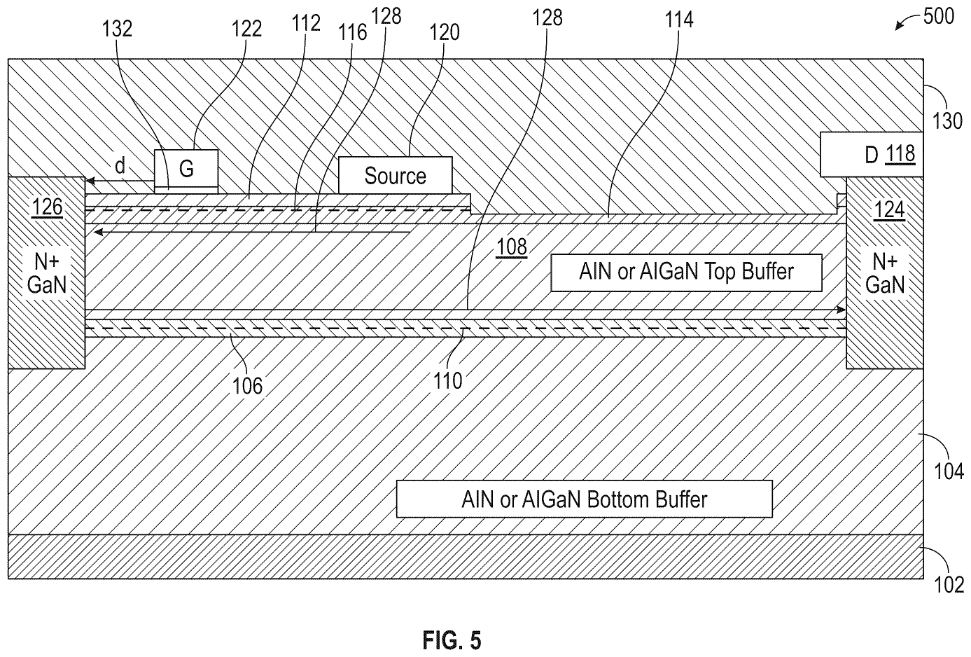

FIG. 5 depicts another example of a transistor device 500 in accordance with this disclosure. FIG. 5 is a cross-sectional view. In the transistor device 500, the first conductive material 124 extends vertically from the drain electrode 118 to the bottom buffer layer 104 and electrically couples the buried first 2DEG channel 110 and the drain electrode 118, and the second conductive material 126 extends vertically between and electrically couples the buried first 2DEG channel 110 and the topside second 2DEG channel 116.

The first conductive material 124 and the second conductive material 126, or “n+ linker regions,” may be formed using MOCVD or Molecular Beam Epitaxy (MBE). However, MOCVD and MBE machines are expensive.

In accordance with this disclosure, the first conductive material 124 and the second conductive material 126 may be formed using sputtering, such as using sputtered GaN or AlGaN. Sputtering machines are less expensive than MOCVD and MBE machines, and sputtering machines are faster, thereby increasing throughput.

The techniques shown in FIG. 5 may be combined with the techniques in one or more of FIG. 1 through FIG. 4, or any of the other techniques of this disclosure, all of which being shown combined in FIG. 9.

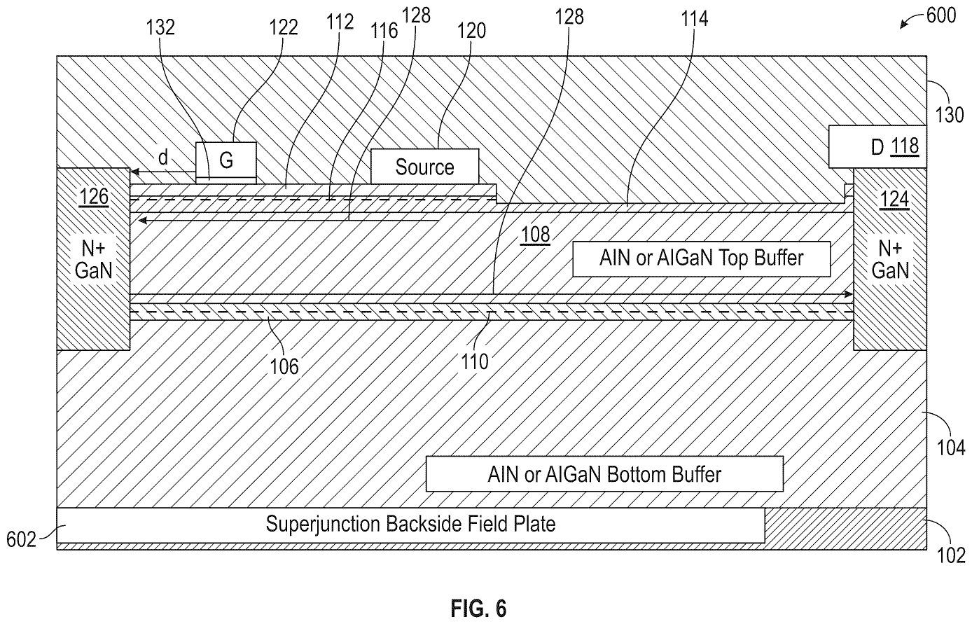

FIG. 6 depicts another example of a transistor device 600 in accordance with this disclosure. FIG. 6 is a cross-sectional view. The transistor device 600 includes a superjunction backside field plate 602. More particularly, the superjunction backside field plate 602 is a p-type implanted region formed by acceptor dopants such as aluminum in the substrate 102, e.g., SiC or SiC/poly-AlN, that is configured to operate as a superjunction. A superjunction is configured to deplete during normal operation of the transistor device 600. A density of p-type dopants in the p-type implanted region, namely the superjunction backside field plate 602, is substantially matched to a density of the electrons in the 2-D electron gas of the buried first 2DEG channel 110. In some examples, the doping density of the acceptor, aluminum may be close to 1E19 dopants per centimeter cubed over 100 nm, so as to have a total carrier concentration of 1E13 holes per centimeter squared after carrier ionization.

The superjunction is a modification of a backside field plate. In addition, the thickness of the bottom buffer layer 104 may be thinner than if the p-type implanted layer is used as a field plate. The reason is that the p-type implanted region when used as a superjunction is completely depleted during the normal operation of the device, and therefore the bottom buffer layer 104 may be thin, but if used as a backside field plate, the layer is not thin.

When the p-type implanted region in the substrate 102, e.g., SiC, is heavily doped, it will act as a field plate, and the p-type conductivity remains there at all times. However, when the region in the substrate 102 is lightly doped, it will act as a superjunction, and the p-type region is depleted, e.g., completely depleted, during the normal operation of the device.

The techniques shown in FIG. 6 may be combined with the techniques in one or more of FIG. 1 through FIG. 5, or any of the other techniques of this disclosure, all of which being shown combined in FIG. 9.

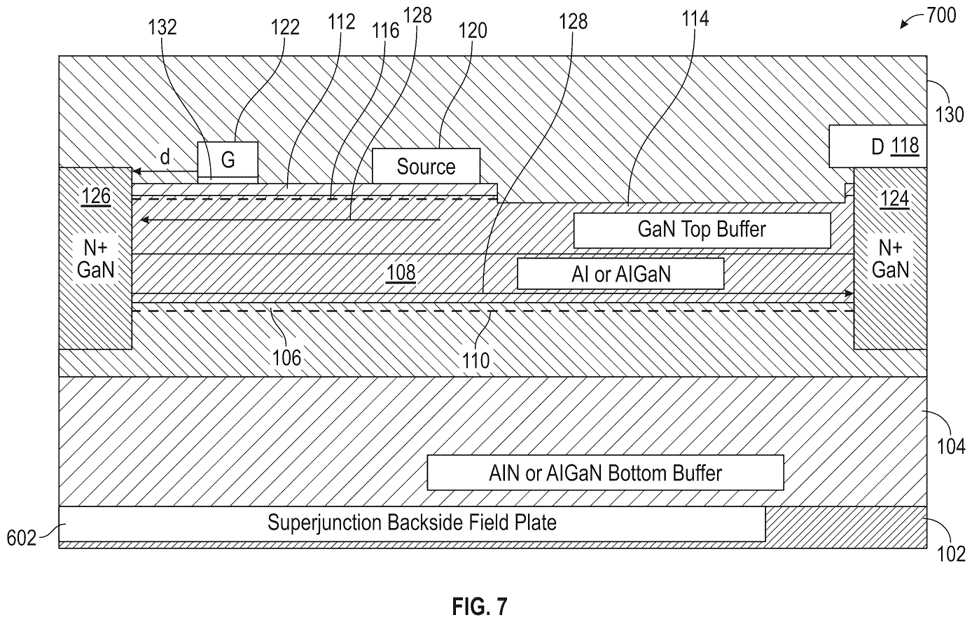

FIG. 7 depicts another example of a transistor device 700 in accordance with this disclosure. FIG. 7 is a cross-sectional view. Like the transistor device 600 of FIG. 6, the transistor device 700 includes a superjunction backside field plate 602, where the superjunction backside field plate 602 is a p-type implanted region in the substrate 102, e.g., SiC or SiC/poly-AlN, that is configured to operate as a superjunction. A superjunction is configured to deplete during normal operation of the transistor device 600. A density of p-type dopants in the p-type implanted region, namely the superjunction backside field plate 602, is substantially matched to a density of the electrons in the 2-D electron gas of the topside second 2DEG channel 116.

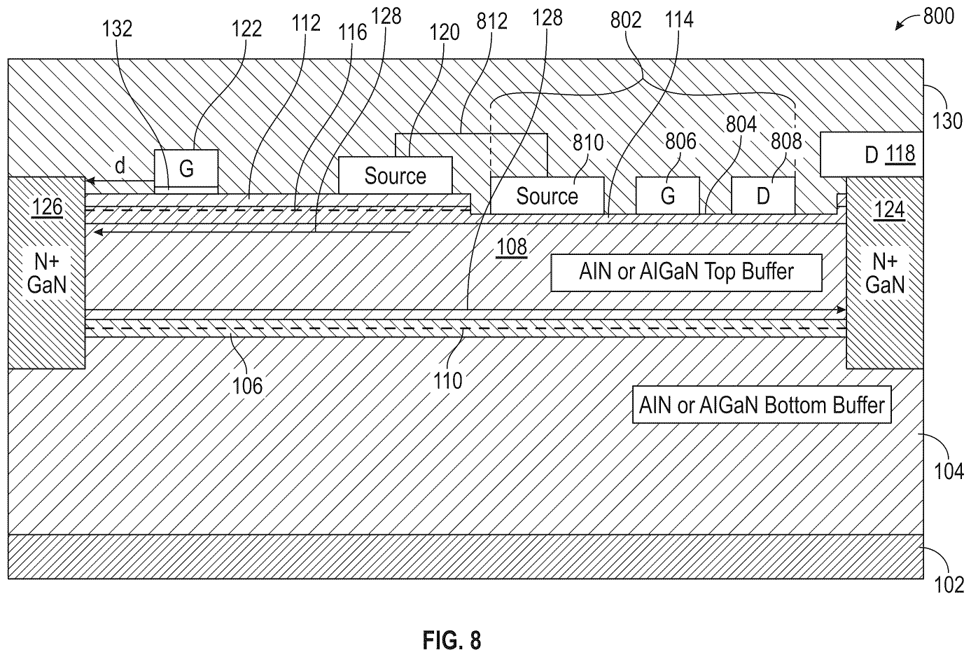

FIG. 8 depicts another example of a transistor device 800 in accordance with this disclosure. FIG. 8 is a cross-sectional view. The p-type transistor device 800 is similar to the transistor device 500 with the addition of an integrated circuit 802 made on top of the device, such as using top-surface GaN devices.

Both n-type and p-type devices may be made. The top buffer layer, namely second semiconductor material layer 108, uniquely enables p-type devices because a p-type doped region may be formed on the fourth semiconductor layer 114 or at the interface of the second semiconductor layer 108 and the fourth semiconductor layer 114 by piezoelectric doping. In some examples, the p-typed doped region is the fourth semiconductor layer 114. The piezoelectric doping is enabled by the top buffer layer because grading the fourth semiconductor material layer 114 from a higher aluminum percentage to a lower aluminum percentage or using GaN as the fourth semicondutor layer 114 may be used to form the p-type channel region.

In this manner, the transistor devices of this disclosure, such as but not limited to the transistor device 500 of FIG. 5, support one or more integrated circuits 802 formed on a top surface 804 of the device. The integrated circuit 802 shown in FIG. 8 includes a gate electrode 806, a drain electrode 808, and a source electrode 810, where the source electrode 810 is electrically coupled with the source electrode 120 by a connector 812.

A p-type integrated circuit 802 is enabled by a p-type doped region formed by piezoelectric doping created by growing a GaN layer or grading an aluminum fraction from a higher aluminum percentage to a lower aluminum percentage in an AlGaN or AlN layer, namely the fourth semiconductor material layer 114.

The techniques shown in FIG. 8 may be combined with the techniques in one or more of FIG. 1 through FIG. 7 and FIG. 9, or any of the other techniques of this disclosure.

FIG. 9 depicts another example of a transistor device 900 in accordance with this disclosure. FIG. 9 is a cross-sectional view. The transistor device 900 includes many of the techniques described above with respect to FIG. 1 through FIG. 8 combined in a single transistor device. For example, the transistor device 900 includes a buried first 2DEG channel 110 and a topside second 2DEG channel 116, a backside field plate 202, a bottom buffer layer 104, a middle buffer layer 314, and a top buffer layer (namely the second semiconductor material layer 108), a superjunction backside field plate 602, a source electrode 120 coupled with a first source field plate 302 and a second source field plate 306, and a gate electrode 122 coupled with a gate field plate 304.

In some examples, the transistor device 900 supports one or more integrated circuits, such as the integrated circuit 802 of FIG. 8, formed on a top surface 902.

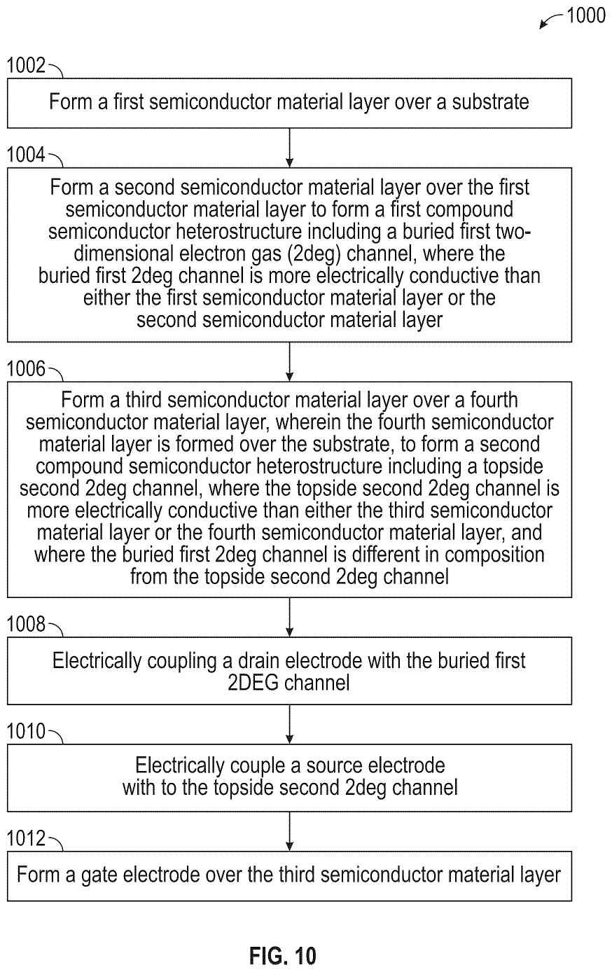

FIG. 10 is a flow diagram of an example of a method of forming a compound semiconductor heterostructure transistor device including multiple two-dimensional electron gas channels. At block 1002, the method 1000 includes forming a first semiconductor material layer over a substrate. For example, the first semiconductor material layer 106 in FIG. 1 is formed over the substrate 102.

At block 1004, the method 1000 includes forming a second semiconductor material layer over the first semiconductor material layer to form a first compound semiconductor heterostructure including a buried first two-dimensional electron gas (2DEG) channel, where the buried first 2DEG channel is more electrically conductive than either the first semiconductor material layer or the second semiconductor material layer. For example, the second semiconductor material layer 108 in FIG. 1 is formed over the first semiconductor material layer 106 to form the buried first 2DEG channel 110.

At block 1006, the method 1000 includes forming a third semiconductor material layer over a fourth semiconductor material layer, where the fourth semiconductor material layer is formed over the substrate, to form a second compound semiconductor heterostructure including a topside second 2DEG channel, where the topside second 2DEG channel is more electrically conductive than either the third semiconductor material layer or the fourth semiconductor material layer, and where the buried first 2DEG channel is different in composition from the topside second 2DEG channel. For example, the third semiconductor material layer 112 in FIG. 1 is formed over the fourth semiconductor material layer 114 to form the topside second 2DEG channel 116, where the topside second 2DEG channel 116 is different in composition from the buried first 2DEG channel 110. For example, the second semiconductor material layer 108 and the third semiconductor material layer 112 are different in composition and, as such, the buried first 2DEG channel 110 and the topside second 2DEG channel 116 are different in composition. The topside second 2DEG channel 116 may be formed using an AlGaN/GaN combination (or an AlN/GaN combination) of the third semiconductor material layer 112 and the fourth semiconductor material layer 114, respectively. In this way, a standard p-GaN enhancement mode transistor device by inserting a p-GaN layer in between the third semiconductor material layer 112 and the gate 122 may be made. In addition, the buried first 2DEG channel 110 may be formed using an AlN/GaN combination of the first semiconductor material layer 106 and the second semiconductor material layer 108, respectively.

At block 1008, the method 1000 includes electrically coupling a drain electrode with the buried first 2DEG channel. For example, the drain electrode 118 in FIG. 1 is electrically coupled with the buried first 2DEG channel 110.

At block 1010, the method 1000 includes electrically coupling a source electrode with the topside second 2DEG channel. For example, the source electrode 120 in FIG. 1 is electrically coupled with the topside second 2DEG channel 116.

At block 1012, the method 1000 includes forming a gate electrode over the third semiconductor material layer. For example, the gate electrode 122 in FIG. 1 is formed over the third semiconductor material layer 112.

In some examples, the method 1000 includes forming a backside field plate between the substrate and the buried first 2DEG channel. For example, the backside field plate 202 in FIG. 2 is formed between the substrate 102 and the buried first 2DEG channel 110. Then, the method 1000 includes forming a top buffer layer between the buried first 2DEG channel and the topside second 2DEG channel, where the top buffer layer includes aluminum. For example, the second semiconductor material layer 108 in FIG. 2 is formed between the buried first 2DEG channel 110 and the topside second 2DEG channel 116, where the second semiconductor material layer 108 includes AlN or AlGaN. Then, the method 1000 includes forming a middle buffer layer between the backside field plate and the buried first 2DEG channel, where the middle buffer layer includes aluminum. For example, the middle buffer layer 204 in FIG. 2 is formed between the backside field plate 202 and the buried first 2DEG channel 110, where the middle buffer layer 204 includes AlN or AlGaN. Then, the method 1000 includes forming a bottom buffer layer between the substrate and the backside field plate, where the bottom buffer layer includes aluminum. For example, the bottom buffer layer 104 in FIG. 2 is formed between the substrate 102 and the backside field plate 202, where the bottom buffer layer 104 includes AlN or AlGaN.

In some examples, the method 1000 includes forming an integrated circuit on a top surface of the device, the integrated circuit comprising a p-type device. For example, the integrated circuit 802 of FIG. 8 is formed on a transistor device, such as the transistor device 500 of FIG. 5 or another of the transistor devices shown in the disclosure. The method 1000 includes forming a p-type doped region in the p-type device by piezoelectric doping created by growing a GaN layer or by grading an aluminum fraction from a higher aluminum percentage to a lower aluminum percentage in an AlGaN layer, for example, the fourth semiconductor layer 114.

In some examples, the method 1000 includes forming a p-type implanted region in the substrate configured to operate as a superjunction, where a density of p-type dopants in the p-type implanted region is substantially matched to a density of the electrons in the buried first 2DEG channel, and where the p-type implanted region is configured to deplete during normal operation of the device, such as shown and described above with respect to FIG. 6.

In some examples, the method 1000 includes forming a backside field plate including a doped region formed by piezoelectric doping, where the doped region is formed by grading an aluminum fraction in an AlGaN layer from a higher aluminum percentage to a lower aluminum percentage, and where a doping concentration is proportional to a rate of change of the aluminum fraction.

In some examples, the method 1000 includes forming, using sputtering, a first conductive material that extends vertically between and electrically couples the drain electrode and the topside second 2DEG channel and forming, using sputtering, a second conductive material, that extends vertically between and electrically couples the buried first 2DEG channel and the topside second 2DEG channel. For example, the first conductive material 124 and the second conductive material 126, such as the transistor device 500 of FIG. 5, are formed using sputtered GaN or AlGaN. The second conductive material is laterally offset from the gate electrode in a plane parallel with the third semiconductor material layer 112 on a side opposite the source electrode, wherein the drain electrode is formed above the first conductive material.

### Various Notes

Each of the non-limiting claims or examples described herein may stand on its own, or may be combined in various permutations or combinations with one or more of the other examples.

The above detailed description includes references to the accompanying drawings, which form a part of the detailed description. The drawings show, by way of illustration, specific embodiments in which the invention may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more claims thereof), either with respect to a particular example (or one or more claims thereof), or with respect to other examples (or one or more claims thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact discs and digital video discs), magnetic cassettes, memory cards or sticks, random access memories (RAMs), read only memories (ROMs), and the like.

The above description is intended to be illustrative, and not restrictive. For example, the above-described examples (or one or more claims thereof) may be used in combination with each other. Other embodiments may be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments may be combined with each other in various combinations or permutations. The scope of the invention should be determined with reference to the appended claims, along with the full scope of equivalents to which such claims are entitled.

What is claimed is:

1. A compound semiconductor heterostructure transistor device including multiple two-dimensional electron gas channels, the compound semiconductor heterostructure transistor device comprising:
a substrate;
a first semiconductor material layer formed over the substrate;
a second semiconductor material layer formed over the first semiconductor material layer to form a first compound semiconductor heterostructure including a buried first two-dimensional electron gas (2DEG) channel, wherein the buried first 2DEG channel is more electrically conductive than either the first semiconductor material layer or the second semiconductor material layer;
a third semiconductor material layer formed over a fourth semiconductor material layer, wherein the fourth semiconductor material layer is formed over the substrate, to form a second compound semiconductor heterostructure including a topside second 2DEG channel, wherein the topside second 2DEG channel is more electrically conductive than either the third semiconductor material layer or the fourth semiconductor material layer, and wherein the buried first 2DEG channel is different in composition from the topside second 2DEG channel;
a drain electrode electrically coupled with the buried first 2DEG channel;
a source electrode electrically coupled with the topside second 2DEG channel; and
a gate electrode formed over the third semiconductor material layer.

2. The compound semiconductor heterostructure transistor device of claim 1, further comprising:
a backside field plate formed between the substrate and the buried first 2DEG channel;
a top buffer layer formed between the buried first 2DEG channel and the topside second 2DEG channel, wherein the top buffer layer includes aluminum;
a middle buffer layer formed between the backside field plate and the buried first 2DEG channel, wherein the middle buffer layer includes aluminum; and
a bottom buffer layer formed between the substrate and the backside field plate, wherein the bottom buffer layer includes aluminum.

3. The compound semiconductor heterostructure transistor device of claim 1, wherein the device is configured to support an integrated circuit formed on a top surface of the device, the integrated circuit comprising a p-type device, and wherein the p-type device includes a piezoelectric doped p-type doped region, wherein the p-type doped region includes an aluminum fraction graded from a higher aluminum percentage to a lower aluminum percentage in an AlGaN layer.

4. The compound semiconductor heterostructure transistor device of claim 1, further comprising:
a p-type implanted region in the substrate configured to operate as a superjunction, wherein a density of p-type dopants in the p-type implanted region is substantially matched to a density of the electrons in the buried first 2DEG channel, and wherein the p-type implanted region is configured to deplete during normal operation of the device.

5. The compound semiconductor heterostructure transistor device of claim 1, wherein the source electrode is configured to operate as a first source field plate with respect to the buried first 2DEG channel, the device further comprising:
a gate field plate in electrical contact with the gate electrode, wherein the gate field plate extends laterally beyond at least one end of the gate electrode; and
a second source field plate in electrical contact with the source electrode, wherein the second source field plate extends laterally beyond at least one end of the source electrode.

6. The compound semiconductor heterostructure transistor device of claim 1, further comprising:
a backside field plate comprising a doped region formed by piezoelectric doping,
wherein the doped region is formed by grading an aluminum fraction in an AlGaN layer from a higher aluminum percentage to a lower aluminum percentage, and
wherein a doping concentration is proportional to a rate of change of the aluminum fraction.

7. The compound semiconductor heterostructure transistor device of claim 1, further comprising:
a first conductive material, formed using sputtering, that extends vertically between and electrically couples the drain electrode and the buried first 2DEG channel; and
a second conductive material, formed using sputtering, that extends vertically between and electrically couples the buried first 2DEG channel and the topside second 2DEG channel,
wherein the second conductive material is laterally offset from the gate electrode on a side opposite the source electrode, wherein the drain electrode is formed above the first conductive material.

8. A method of forming a compound semiconductor heterostructure transistor device including multiple two-dimensional electron gas channels, the method comprising:
forming a first semiconductor material layer over a substrate;
forming a second semiconductor material layer over the first semiconductor material layer to form a first compound semiconductor heterostructure including a buried first two-dimensional electron gas (2DEG) channel, wherein the buried first 2DEG channel is more electrically conductive than either the first semiconductor material layer or the second semiconductor material layer;
forming a third semiconductor material layer over a fourth semiconductor material layer, wherein the fourth semiconductor material layer is formed over the substrate, to form a second compound semiconductor heterostructure including a topside second 2DEG channel, wherein the topside second 2DEG channel is more electrically conductive than either the third semiconductor material layer or the fourth semiconductor material layer, and wherein the buried first 2DEG channel is different in composition from the topside second 2DEG channel;
electrically coupling a drain electrode with the buried first 2DEG channel;
electrically coupling a source electrode with the topside second 2DEG channel; and
forming a gate electrode over the third semiconductor material layer.

9. The method of claim 8, comprising:
forming a backside field plate between the substrate and the buried first 2DEG channel;
forming a top buffer layer between the buried first 2DEG channel and the topside second 2DEG channel, wherein the top buffer layer includes aluminum;
forming a middle buffer layer between the backside field plate and the buried first 2DEG channel, wherein the middle buffer layer includes aluminum; and
forming a bottom buffer layer between the substrate and the backside field plate, wherein the bottom buffer layer includes aluminum.

10. The method of claim 8, comprising:
forming an integrated circuit on a top surface of the device, the integrated circuit comprising a p-type device; and
forming a p-type doped region in the p-type device by piezoelectric doping created by growing a GaN layer.

11. The method of claim 8, further comprising:
forming a p-type implanted region in the substrate configured to operate as a superjunction, wherein a density of p-type dopants in the p-type implanted region is substantially matched to a density of the electrons in the buried first 2DEG channel, and wherein the p-type implanted region is configured to deplete during normal operation of the device.

12. The method of claim 8, comprising:
forming an integrated circuit on a top surface of the device, the integrated circuit comprising a p-type device; and
forming a p-type doped region in the p-type device by piezoelectric doping created grading an aluminum fraction from a higher aluminum percentage to a lower aluminum percentage in an AlGaN layer.

13. The method of claim 8, comprising:
forming, using sputtering, a first conductive material that extends vertically between the bottom buffer layer and the drain electrode and electrically couples the drain electrode and the topside second 2DEG channel; and
forming, using sputtering, a second conductive material, that extends vertically between and electrically couples the buried first 2DEG channel and the topside second 2DEG channel,
wherein the second conductive material is laterally offset from the gate electrode on a side opposite the source electrode, wherein the drain electrode is formed above the first conductive material.

14. The method of claim 8, wherein the source electrode is configured to operate as a first source field plate with respect to the buried first 2DEG channel, the method comprising:
forming a gate field plate in electrical contact with the gate electrode, wherein the gate field plate extends laterally beyond at least one end of the gate electrode; and
forming a second source field plate in electrical contact with the source electrode, wherein the second source field plate extends laterally beyond at least one end of the source electrode.

15. The method of claim 8, comprising:
forming a backside field plate comprising a doped region formed by piezoelectric doping, including:
forming the doped region by grading an aluminum fraction in an AlGaN layer from a higher aluminum percentage to a lower aluminum percentage, wherein a doping concentration is proportional to a rate of change of the aluminum fraction.

16. A compound semiconductor heterostructure transistor device including multiple two-dimensional electron gas channels in combination with an integrated circuit, the combination comprising:
a substrate;
a first semiconductor material layer formed over the substrate;
a second semiconductor material layer formed over the first semiconductor material layer to form a first compound semiconductor heterostructure including a buried first two-dimensional electron gas (2DEG) channel, wherein the buried first 2DEG channel is more electrically conductive than either the first semiconductor material layer or the second semiconductor material layer;
a third semiconductor material layer formed over a fourth semiconductor material layer, wherein the fourth semiconductor material layer is formed over the substrate, to form a second compound semiconductor heterostructure including a topside second 2DEG channel, wherein the topside second 2DEG channel is more electrically conductive than either the third semiconductor material layer or the fourth semiconductor material layer, and wherein the buried first 2DEG channel is different in composition from the topside second 2DEG channel;
a first drain electrode electrically coupled with the buried first 2DEG channel;
a first source electrode electrically coupled with the topside second 2DEG channel; and
a first gate electrode formed over the third semiconductor material layer; and
the integrated circuit including:
a second gate electrode coupled with the fourth semiconductor material layer;
a second drain electrode coupled with the fourth semiconductor material layer; and
a second source electrode coupled with the fourth semiconductor material layer and the first source electrode,
wherein the integrated circuit is positioned on a top surface of the compound semiconductor heterostructure transistor device.

17. The combination of claim 16, further comprising:
a backside field plate formed between a bottom buffer layer and the buried first 2DEG channel.

18. The combination of claim 17, further comprising:
a p-type implanted region formed in the substrate configured to operate as a superjunction.

19. The combination of claim 16, wherein the first source electrode is configured to operate as a first source field plate with respect to the buried first 2DEG channel, the device further comprising:
a gate field plate in electrical contact with the first gate electrode, wherein the gate field plate extends laterally beyond at least one end of the first gate electrode; and
a second source field plate in electrical contact with the first source electrode, wherein the second source field plate extends laterally beyond at least one end of the first source electrode.

20. The combination of claim 16, comprising:
a first conductive material that extends vertically between the bottom buffer layer and the drain electrode and electrically couples the drain electrode and the buried first 2DEG channel; and
a second conductive material that extends vertically between and electrically couples the buried first 2DEG channel and the topside second 2DEG channel,
wherein the second conductive material is laterally offset from the gate electrode on a side opposite the source electrode, wherein the drain electrode is formed above the first conductive material.
